(19) United States
(12) Patent Application Publication
(10) Pub. No.: US 2024/0266165 A1
(43) Pub. Date: Aug. 8, 2024

(54) III-V, II-VI IN-SITU COMPLIANT SUBSTRATE FORMATION

(71) Applicant: The Regents of the University of California, Oakland, CA (US)

(72) Inventors: Shuji Nakamura, Santa Barbara, CA (US); Steven P. DenBaars, Goleta, CA (US)

(73) Assignee: The Regents of the University of California, Oakland, CA (US)

(21) Appl. No.: 18/567,162

(22) PCT Filed: Jun. 3, 2022
(86) PCT No.: PCT/US22/32102

§ 371 Date: Dec. 5, 2023

Related U.S. Application Data
(60) Provisional application No. 63/197,740, filed on Jun. 7, 2021.

(51) Int. Cl. H01L 21/02

(52) U.S. Cl. CPC H01L 21/02334; H01L 21/02381; H01L 21/0242; H01L 21/0254; H01L 21/0262

(57) ABSTRACT

A III-V or II-VI compound based device is fabricated having one or more layers with an in-plane lattice constant or strain that is at least 20% biaxially relaxed, preferably more than 20% biaxially relaxed, more preferably 50% or more biaxially relaxed, and most preferably at least 70% biaxially relaxed. A III-V or II-VI compound based decomposition stop layer is created on or above a III-V or II-VI compound based decomposition layer, wherein the III-V or II-VI compound based decomposition stop layer has a higher sublimation temperature or melting point as compared to a lower sublimation temperature or melting point of the III-V or II-VI compound based decomposition layer, and a temperature increase decomposes the III-V or II-VI compound based decomposition layer. A III-V or II-VI compound based device structure is grown on or above the III-V or II-VI compound based decomposition stop layer.

### CROSS REFERENCE TO RELATED APPLICATIONS

This application claims the benefit under 35 U.S.C. Section 119(e) of the following co-pending and commonly-assigned application:
U.S. Provisional Application Ser. No. 63/197,740, filed on Jun. 7, 2021, by Shuji Nakamura and Steven P. DenBaars, entitled “III-V, II-VI IN-SITU COMPLIANT SUBSTRATE FORMATION,” attorneys' docket number G&C 30794.0803USP1 (UC 2021-889-1);
which application is incorporated by reference herein.

This application is related to the following co-pending and commonly-assigned applications:
PCT International Patent Application Serial No. PCT/US22/218264, filed on May 9, 2022, by Philip Chan, Steven P. DenBaars and Shuji Nakamura, entitled “III-NITRIDE BASED DEVICES GROWN ON A THIN TEMPLATE ON THERMALLY DECOMPOSED MATERIAL,” attorneys' docket number G&C 30794.0802WOU1 (UC 2021-888-3), which application claims the benefit under 35 U.S.C. Section 119(e) of the following co-pending and commonly-assigned applications: U.S. Provisional Application Ser. No. 63/186,749, filed on May 10, 2021, by Philip Chan, Steven P. DenBaars and Shuji Nakamura, entitled “III-NITRIDE BASED DEVICES GROWN ON A THIN TEMPLATE ON THERMALLY DECOMPOSED MATERIAL,” attorneys' docket number G&C 30794.0802USP1 (UC 2021-888-1); and U.S. Provisional Application Ser. No. 63/230,205, filed on Aug. 6, 2021, by Philip Chan, Steven P. DenBaars and Shuji Nakamura, entitled “III-NITRIDE BASED DEVICES GROWN ON A THIN TEMPLATE ON THERMALLY DECOMPOSED MATERIAL,” attorneys' docket number G&C 30794.0802USP2 (UC 2021-888-2);
U.S. Provisional Application Ser. No. 63/240,517, filed on Sep. 3, 2021, by Norleakvisoth Lim, Philip Chan, Steven P. DenBaars, Michael J. Gordon and Shuji Nakamura, entitled “III-NITRIDE-BASED DEVICES GROWN WITH A RELAXED ACTIVE REGION,” attorneys' docket number G&C 30794.0806USP1 (UC 2022-760-1);
U.S. Provisional Application Ser. No. 63/245,105, filed on Sep. 16, 2021, by Philip Chan, Steven P. DenBaars and Shuji Nakamura, entitled “SURFACE MORPHOLOGY OF III-NITRIDE-BASED DEVICES GROWN ON OR ABOVE A STRAIN COMPLIANT TEMPLATE,” attorneys' docket number G&C 30794.0808USP1 (UC 2022-763-1); and
U.S. Provisional Application Ser. No. 63/305,441, filed on Feb. 1, 2022, by Philip Chan, Hsun-Ming Chan, Vincent Rienzi and Shuji Nakamura, entitled “III-NITRIDE-BASED HIGH EFFICIENCY AND HIGH-POWER DEVICES GROWN ON OR ABOVE A STRAIN RELAXED TEMPLATE,” attorneys' docket number G&C 30794.0813USP1 (UC 2022-775-1);
all of which applications are incorporated by reference herein.

### STATEMENT REGARDING FEDERALLY SPONSORED RESEARCH AND DEVELOPMENT

This invention was made with Government support under Grant No. HR001120C0135 awarded by the Defense Advanced Research Projects Agency (DARPA). The Government has certain rights in this invention.

### BACKGROUND OF THE INVENTION

### 1. Field of the Invention

This invention relates to methods of III-V, II-VI in-situ compliant substrate formation and resulting devices.

### 2. Description of the Related Art

(Note: This application references a number of different publications as indicated throughout the specification by one or more reference numbers in brackets, e.g., [x]. A list of these different publications ordered according to these reference numbers can be found below in the section entitled “References.” Each of these publications is incorporated by reference herein.)

III-V compounds such as binary III-V compounds of GaAs, GaP, InP, InAs, AlP, AlAs, AlSb, GaSb, GaN, InN, AlN and others are used to make many kinds of optoelectronic and electronic devices [1]. Those devices are composed of binary, ternary and quaternary III-V compounds by mixing the binary III-V compounds.

In order to make III-V compound based devices, hetero-structures are used. For example, an AlGaAs or AlInGaP light emitting diode (LED) is grown on a GaAs template or substrate under lattice-matched conditions by adjusting a lattice constant of the AlGaAs or AlInGaP to be same as that of the GaAs template or substrate by changing the composition. If there is a lattice mismatch, misfit dislocations are originated in the AlGaAs or AlInGaP layer, and then device performance, such as device life time or LED efficiency, becomes poor [1].

Thus, there is a need in the art for methods for minimizing or preventing the generation of misfit dislocations caused by lattice mismatch. The present invention satisfies this need.

### SUMMARY OF THE INVENTION

To overcome the limitations of the prior art described above, the present invention discloses a III-V or II-VI compound based device that is fabricated having an in-plane lattice constant or strain that is at least 20% biaxially relaxed, by creating a III-V or II-VI compound based decomposition stop layer on or above a III-V or II-VI compound based decomposition layer, wherein the III-V or II-VI compound based decomposition stop layer has a higher sublimation temperature or melting point as compared to a lower sublimation temperature or melting point of the III-V or II-VI compound based decomposition layer, and a temperature is increased to decompose the III-V or II-VI compound based decomposition layer; and growing a III-V or II-VI compound based device structure on or above the III-V or II-VI compound based decomposition stop layer. The III-V or II-VI compound based device structure includes at least one of an n-type layer, active layer, and p-type layer, and at least one of the n-type layer, active layer and p-type layer has an in-plane lattice constant or strain that is at least 20% biaxially relaxed, preferably more than 20% biaxially relaxed, more preferably 50% or more biaxially relaxed, and most preferably at least 70% biaxially relaxed.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Referring now to the drawings in which like reference numbers represent corresponding parts throughout:

FIGS. 1(a) and 1(b) illustrate prior art device structures comprised of a GaAs substrate with AlInGaP grown thereon.

FIG. 2(a) illustrates a device structure for an embodiment of the present invention that is fabricated using metal organic chemical vapor deposition (MOCVD) growth.

FIG. 2(b) illustrates a device structure for an embodiment of the present invention that is fabricated using MOCVD growth.

FIG. 3(a) show a prior art device structure comprised of an Si substrate with a GaAs layer grown on an Si substrate.

FIG. 3(b) illustrates a device structure for an embodiment of the present invention that starts with an Si substrate and an Si template grown thereon.

FIG. 4 is a graph of bandgap energy (eV) and wavelength (μm) of III-V compound semiconductors as a function of lattice constant (Å).

FIG. 5 illustrates a device structure for an embodiment of the present invention.

FIG. 6 is a flowchart that illustrates the steps for a process of fabricating a III-V or IT-VI based device, according to the present invention.

### DETAILED DESCRIPTION OF THE INVENTION

In the following description of the preferred embodiment, reference is made to the accompanying drawing which forms a part hereof, and in which is shown by way of illustration a specific embodiment in which the invention may be practiced. It is to be understood that other embodiments may be utilized, and structural changes may be made without departing from the scope of the present invention.

### Overview

Using the present invention, the generation of lattice misfit dislocations caused by lattice mismatch is minimized or prevented perfectly. A thin decomposition stop layer comprising a III-V or II-VI compound based layer with a higher sublimation temperature or melting point is grown on or above a decomposition layer comprising a III-V or II-VI compound based layer with a lower sublimation temperature or lower melting point. Then, the temperature is increased to decompose the decomposition layer, while maintaining a good surface morphology for the decomposition stop layer. After the decomposition of the decomposition layer, the thin decomposition stop layer becomes like a free-standing, flexible plate. Next, a device structure is grown with a biaxially relaxed lattice constant and without the formation of misfit dislocations, despite a large lattice mismatch.

### Technical Description

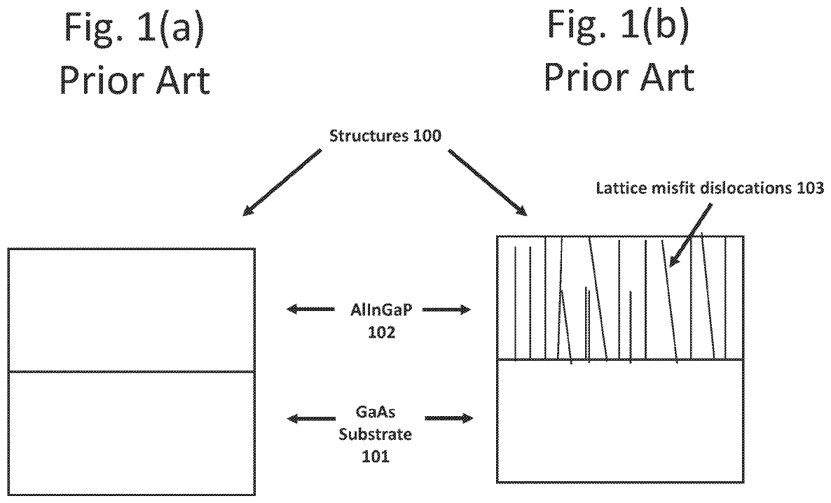

FIGS. 1(a) and 1(b) illustrate prior art device structures 100 comprised of a GaAs substrate 101 with AlInGaP 102 grown thereon. When AlInGaP 101 is grown on the GaAs substrate 101, the composition of AlInGaP 102 is adjusted for a lattice constant to be same as that of the GaAs substrate 101 to prevent lattice mismatch and the formation of lattice misfit dislocations, as shown in FIG. 1(a). Thus, only a certain composition of AlInGaP 102 is grown on the GaAs substrate 101.

If the AlInGaP 102 is grown on the GaAs substrate 101 with a different lattice constant than the GaAs substrate 101, resulting in a lattice mismatch and then the lattice misfit dislocations 103 are originated, as shown in FIG. 1(b). The formation of the lattice misfit dislocations 103 causes poor LED device performance including a short life time and a lower efficiency.

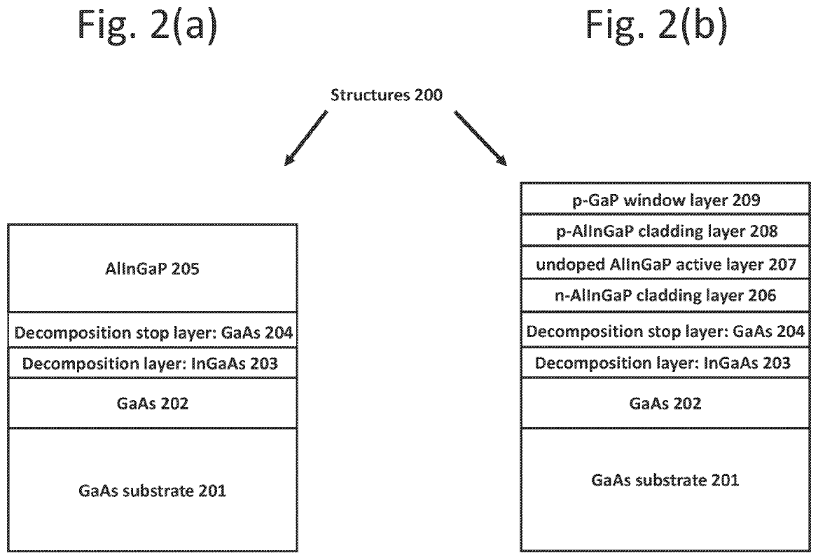

FIG. 2(a) illustrates a device structure 200 for an embodiment of the present invention that is fabricated using MOCVD growth. Beginning with a GaAs substrate 201, a GaAs template 202 is grown thereon at a temperature of 720° C., followed by a decomposition layer 203 comprised of 3 nm thick InGaAs grown at a low temperature of 650° C. Then, a decomposition stop layer 204 comprised of 100 nm thick GaAs is grown at a high temperature of 720° C. During the growth of the decomposition stop layer 204, the decomposition layer 203 is decomposed into indium (In) and gallium (Ga) metals and arsenide (As). The decomposition stop layer 204 becomes an almost free-standing, flexible layer. When an AlInGaP layer 205 is grown on or above the decomposition stop layer 204, the AlInGaP layer 205 is grown with a biaxially relaxed in-plane lattice constant or strain, even if the lattice constant of the AlInGaP layer 205 is different from that of the decomposition stop layer 204. Thus, when the AlInGaP layer 205 is grown on or above the decomposition stop layer 204, under a lattice mismatch condition, there is no formation of misfit dislocations.

FIG. 2(b) illustrates a device structure 200 for an embodiment of the present invention that is fabricated using MOCVD growth. In this embodiment, the device structure 200 comprises an AlInGaP LED device structure 200 grown on a GaAs substrate 201, and comprises a GaAs template 202 grown at a temperature of 720° C., followed by a decomposition layer 203 comprised of 3 nm thick InGaAs grown at a low temperature of 650° C., followed by a decomposition stop layer 204 comprised of 100 nm thick GaAs is grown at a high temperature of 720° C. An n-AlInGaP cladding layer 206 is grown on or above the decomposition stop layer 204, followed by an undoped AlInGaP active layer 207, a p-AlInGaP cladding layer 208, and a p-GaP window layer 209.

Using the present invention, AlInGaP can be grown with a wide range of compositions on above a thin GaAs layer that is a decomposition stop layer without lattice mismatch, or the formation of lattice misfit dislocations, or at least minimizing the formation of lattice misfit dislocations. Thus, LED performance of life time and efficiency would be improved. Also, the available emission wavelength range of the LED becomes wider, because various compositions of AlInGaP can be grown on the GaAs substrate using the present invention.

As mentioned in FIG. 2(a), even if the first n-AlInGaP cladding layer 206 is grown with a large lattice mismatch from that of the decomposition stop layer 204, there is no formation of misfit dislocations. Other layers 207, 208, 209 of the LED device structure 200 are grown on the n-AlInGaP layer 206 coherently with a biaxially relaxed lattice constant and strain without formation of misfit dislocations or with minimizing the formation of misfit dislocations.

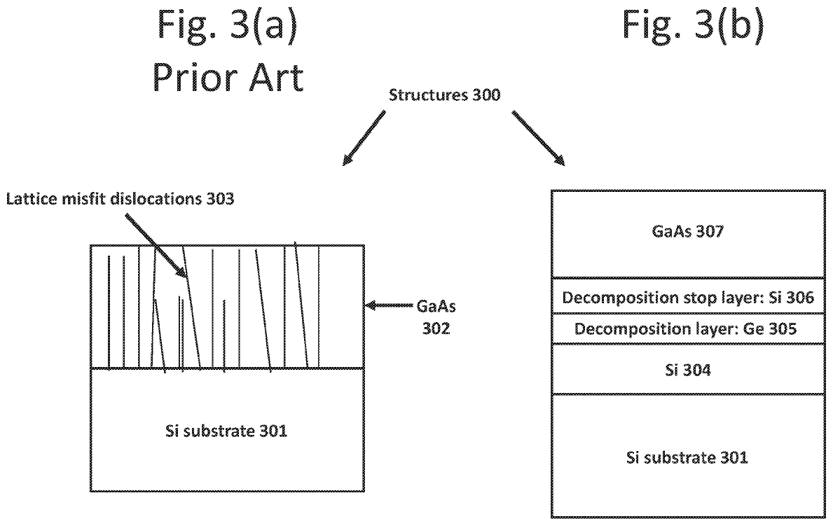

FIG. 3(a) show a prior art device structure 300, comprised of an Si substrate 301 with a GaAs layer 302 grown on the Si substrate 301. Due to a large lattice mismatch between Si and GaAs, a large number of lattice misfit dislocations 303 are generated in the GaAs layer 302. When a III-V compound based device structure is grown on the GaAs layer 302, device performance is very poor due a large number of lattice misfit dislocations 303.

FIG. 3(b) illustrates a device structure 300 for an embodiment of the present invention that starts with an Si substrate 301 with an Si template 304 grown thereon. A decomposition layer 305 comprised of 3 nm thick Ge with a melting point of 938° C. is grown at a low temperature of 600-700° C. by chemical vapor deposition (CVD) on or above the Si template 304, followed by a decomposition stop layer 306 comprised of 100 nm thick Si with a melting point of 1414° C. grown at a high temperature of 900-1000° C. by CVD. During the high temperature growth of the decomposition stop layer 306, or by increasing the temperature further after growth of the decomposition stop layer 306, the decomposition layer 305 is decomposed or melted, and the decomposition stop layer 306 becomes an almost free-standing, flexible layer. The decomposed or melted Ge of the decomposition layer 305 means that a single crystal Ge becomes a polycrystal, amorphous-like crystal, or some amount of Ge is melted away from the layer 305 and some voids are formed. When a GaAs layer 307 is grown on or above the decomposition stop layer 306, the GaAs layer 307 is partially or fully relaxed without the formation of the lattice misfit dislocations 303. When a III-V compound based device structure is grown on the GaAs layer 307, device performance is very good without any lattice misfit dislocations 303.

In another embodiment, using ion implantation, Ge ions are implanted in a top surface of the Si layer 304 to form a decomposition layer 305 comprised of Ge. The depth of the ion implantation, for example, may be is set to be 100 nm. After the ion implantation of Ge, thermal annealing is performed at a high temperature to decompose or melt the decomposition layer 305. Then, a top layer of the Si layer 304 is a decomposition stop layer 306 with a thickness of 100 nm and, after decomposition, is an almost free-standing, flexible layer 306.

Similarly, In ions may be implanted into the Si layer 304 to form the decomposition layer 305, wherein the In reacts and melts together with the Si layer 304 after thermal annealing. Again, a top layer of the Si layer 304 is a decomposition stop layer 306 and, after decomposition, is an almost free-standing, flexible layer.

A device structure 300 is grown on or above the decomposition stop layer 306 comprised of Si, and part or all of the layers of the device structure 300 have a partially or fully relaxed in-plane lattice constant or strain without forming lattice misfit dislocations 303.

Another embodiment would grow the GaAs layer 307 with a thickness of 1 μm or more without lattice misfit dislocations 303, as shown in FIG. 3(b). When the GaAs layer 307 has a thickness of 1-10 μm, and the device structure 300 is grown on the thick GaAs layer 307, all or parts of the layers of the device structure 300 are grown coherently on the thick GaAs layer 307, which means that the thick GaAs layer 307 works as a substrate.

Another embodiment would grow SiC (not shown) with a thickness of more than 200 μm on or above the decomposition stop layer 306 comprised of Si without a lattice mismatch or lattice misfit dislocations 303 by using CVD, wherein the Si substrate 301 is removed after the growth by lapping and etching, and an SiC substrate is obtained.

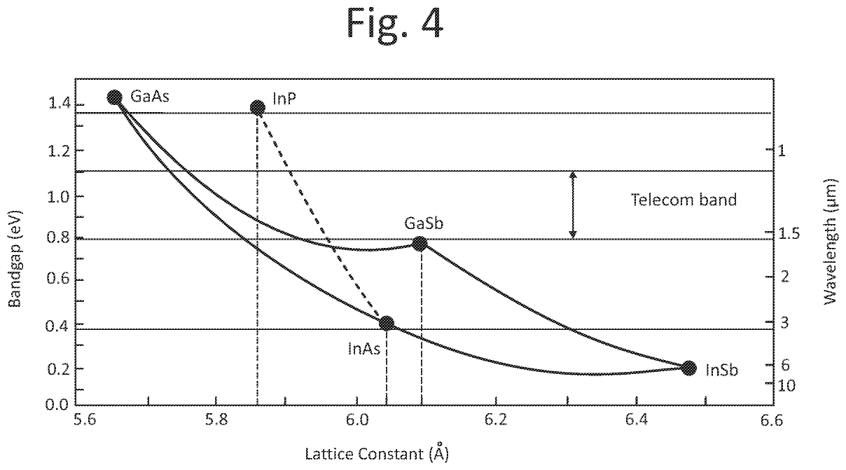

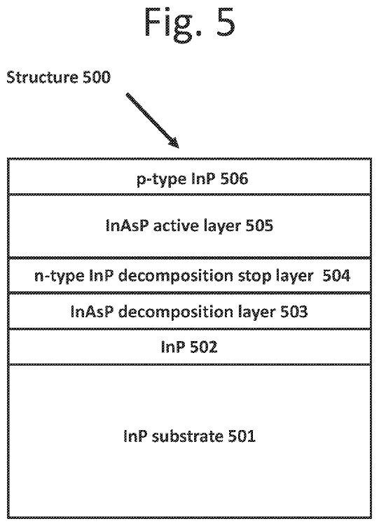

Another embodiment is shown in FIGS. 4 and 5. FIG. 4 is a graph of bandgap energy (eV) and wavelength (μm) of III-V compound semiconductors as a function of lattice constant (Å). Currently, devices emitting at wavelengths of 1.2 μm to 1.6 μm, such as laser diodes (LDs) and LEDs or detectors, are used for telecommunications applications [2], as indicated in the “Telecom band.”

One good material for these telecommunications applications should be InAsP grown on an InP substrate, which is shown as a dotted line in FIG. 4 [2]. However, the lattice constant of InP is always different from that of InAsP with an emitting wavelength of 1.2 μm to 1.6 μm [2]. Thus, when an InAsP active layer with an emitting wavelength of 1.2 μm to 1.6 μm is grown on or above an InP substrate, a lot of misfit dislocations are generated. In order to prevent the generation of misfit dislocations, InAsP has been grown on InP nanowires and nanorods to relax the strain caused by the large lattice mismatch between InAsP and InP. However, conventional methods of fabricating nanowires and nanorods involves a complicated nanosized process [2].

FIG. 5 illustrates a device structure 500 for an embodiment of the present invention. An InP substrate 501 is provided, upon which is grown an InP template 502, followed by a 3 nm thick InAsP decomposition layer 503 grown at a low temperature of about 400-500° C. The InAsP decomposition layer 503 could be grown under a lattice matched condition by adjusting the composition to improve the crystal quality of the next growth of a 200 nm thick n-type InP decomposition stop layer 504 at a high temperature of about 600° C. During the high temperature growth of the n-type InP decomposition stop layer 504, the InAsP decomposition layer 503 is decomposed into In metal and As/P vapor gas. Then, the n-type InP decomposition stop layer 504 becomes a thin, free-standing, flexible, compliant template. Next, an InAsP active layer 505 with an emission wavelength of 1.2 μm to 1.6 μm is grown on the n-type InP decomposition stop layer 504. A large strain caused by a large lattice mismatch between InAsP and InP is biaxially relaxed by the compliant nature of the thin n-type InP composition stop layer 504 without the formation of misfit dislocations, or minimizing the formation of misfit dislocations. Then, a p-type InP layer 506 is grown coherently on the InAsP active layer 505. The n-InP 504/InAsP active layer 505/p-type InP 506 is a basic structure for an LD and LED to emit a wavelength of 1.2 μm to 1.6 μm. Other layers, such as n- or p-contact layers, could be added to this structure 500.

Using the present invention, the whole area of the epitaxial wafer is available for device fabrication. Thus, conventional device fabrication process could be used. For LDs, a 600 μm×1 mm sized edge-emitting LD chip is easily fabricated; for LEDs, a 500 μm×500 μm sized LED chip is easily fabricated. On the other hand, conventional nanowires and nanorods use nanosizes less than 5 nm, and the process is complicated even if the nanowires and nanorods would work to relax the strain caused by a large lattice mismatch.

The present invention is applicable for all kinds of III-V compound based devices, because all of the devices have to use a heterostructure, which originates lattice misfit dislocations at an interface of the heterostructure when there is a lattice mismatch at the interface of the heterostructure. Using the present invention, on the other hand, the formation of misfit dislocations is prevented at the interface of heterostructure of the device, even when grown under a large lattice mismatch condition. Then, the device performance is much better and also noble devices could be developed, because the heterostructure is grown under a relatively large lattice mismatch condition without the formation of misfit dislocations.

For example, III-V compound based devices have been grown on Si substrates to develop optical ICs. However, due to a large lattice mismatch between III-V compound based material and Si, a large number of misfit dislocations are generated. Due to the large number of the misfit dislocations, III-V compound based devices have never been realized on Si substrates. Using the present invention, a III-V compound based device may be grown directly on a Si substrate without lattice mismatch or the a formation of the lattice misfit dislocations.

### Alternatives and Modifications

A number of alternatives and modifications are available for the present invention, as described in more detail below.

In one embodiment, the substrate may comprise GaAs, Si, InP, or other materials.

In one embodiment, the III-V compound may be a binary, ternary or quaternary alloy containing elements from group III (B, Al, Ga, In) and group V (N, P, As, Sb), including binary III-V compounds such as GaAs, GaP, InP, InAs, AlP, AlAs, AlSb, GaSb, AlN, GaN, and InN, and ternary and quaternary III-V compounds resulting from mixing the binary III-V compounds.

In one embodiment, the II-VI compound may include binary II-VI compounds such as ZnSe, ZnS, CdTe, HgTe, ZnO, and MgS, and ternary and quaternary II-VI compounds resulting from mixing the binary II-VI compounds.

In one embodiment, the III-V or II-VI compound based decomposition layer may have a thickness of less than 50 nm, and more preferably, the III-V or II-VI compound based decomposition layer may have a thickness of less than 10 nm. The III-V or II-VI compound based decomposition stop layer has a thickness of 10 nm to 1000 nm.

In one embodiment, the III-V or II-VI compound based device layers grown on the III-V or II-VI compound based decomposition layer have an in-plane lattice constant or strain that is at least 20% biaxially relaxed, preferably more than 20% biaxially relaxed, more preferably 50% or more biaxially relaxed, and most preferably at least 70% biaxially relaxed.

In one embodiment, the III-V or II-VI compound based decomposition stop layer comprises Si, the III-V or II-VI compound based decomposition layer comprises Ge, and the III-V or II-VI compound based device structure comprises one or more SiC layers. At least one of the SiC layers may have an area or size that is more than 100 μm², and the at least one of the SiC layers may be biaxially relaxed more than 20%, and more preferably, the at least one of the SiC layers may be biaxially relaxed more than 50%. At least one of the SiC layers may have a thickness of more than 1 μm, more preferably, the at least one of the SiC layers may have a thickness of more than 5 μm, and most preferably, the at least one of the SiC layers may have a thickness of more than 10 μm. The SiC layers may be used as a substrate to grow the III-V or II-VI compound based device structure, after the III-V or II-VI compound based decomposition stop layer that comprises Si is removed.

In one embodiment, a single layer of decomposition layer would be the best, in view of the simplicity of the growth and decomposition processes.

### Features and Elements

The present invention comprises a number of features and elements, as described in more detail below.

1) A decomposition stop layer of III-V compound based material with a higher sublimation temperature or melting point is grown on or above a decomposition layer of III-V compound based material with a lower sublimation temperature or melting point and then the temperature is increased to decompose the decomposition layer of III-V compound based material with the lower sublimation temperature or melting point.

2) A III-V compound based substrate or III-V template grown on a substrate, wherein ions are implanted with a certain depth from a top surface to form a material called a decomposition layer which has a lower sublimation temperature or melting point. Then, the III-V compound based substrate or III-V template grown on a substrate is annealed at a higher temperature than the lower sublimation temperature or melting point to decompose or melt the decomposition layer with the lower sublimation temperature or melting point. An upper layer from the decomposed decomposition layer is called a decomposition stop layer which has a higher sublimation temperature or melting point.

3) In 2), the ions include at least In, Ga or Al.

4) In 1-3), the III-V compound based device structure is grown on or above the decomposition stop layer of III-V compound based material with the higher sublimation temperature or melting point.

5) In 4), the III-V compound based device structure includes at least an n-type layer.

6) In 4), the III-V compound based device structure includes at least a p-type layer.

7) In 4), the III-V compound based device structure includes at least an n-type layer and p-type layer.

8) In 4), the III-V compound based device structure includes at least n-type layers, an active (emitting) layer and p-type layers.

9) In 8), a top layer of the device structure is flip-chip bonded on a sub-mount, and the device structure is separated from the decomposed III-V compound based decomposition layer (except for III-nitride material) with the lower sublimation temperature or melting point.

10) In 4-9), the III-V compound based device includes all kinds of devices, such as LEDs, LDs, photodetectors, power devices, radio frequency (RF) devices, high electron mobility transistors (HEMTs), field effect transistors (FETs), and other opto-electronic devices.

11) In 10), the III-V compound based devices are used for automobiles including electric vehicles (EVs), data centers, power grids, computers, robots, smartphones, TVs, base stations of wireless communications, all kinds of communication systems, displays, lighting, trains, airplanes, and all kinds of equipment and systems.

12) III-V compound based layers having a grown area of more than 100 m², wherein the in-plane lattice constant or strain of at least one III-V compound based layer is biaxially relaxed more than 50%.

13) A III-V compound based device having a chip size of more than 100 μm², wherein the in-plane lattice constant or strain of at least one III-V compound layer based layer of the device is biaxially relaxed more than 50%.

14) III-V compound based layers, wherein the in-plane lattice constant or strain of at least one III-V compound based layer is biaxially relaxed more than 50%.

15) A III-V compound based device, wherein the in-plane lattice constant or strain of at least one III-nitride based layer is biaxially relaxed more than 50%.

16) III-V compound based layers, wherein the in-plane lattice constant or strain of at least one III-V compound layer is biaxially relaxed more than 70%.

17) A III-V compound based device, wherein the in-plane lattice constant or strain of at least one III-V compound layer is biaxially relaxed more than 70%.

18) In 12-17), the III-V compound based device includes all kinds of devices, such as LEDs, LDs, photodetectors, power devices, radio frequency (RF) devices, high electron mobility transistors (HEMTs), field effect transistors (FETs), and other opto-electronic devices.

19) In 18), the III-V compound based devices are used for automobiles including electric vehicles (EVs), data centers, power grids, computers, robots, smartphones, TVs, base stations of wireless communications, all kinds of communication systems, displays, lighting, trains, airplanes, and all kinds of equipment and systems.

20) In 1-19), the thickness of the decomposition layer is less than 50 nm.

21) In 1-19), the thickness of the decomposition layer is less than 10 nm.

22) In 1-21), the thickness of the decomposition stop layer is from 10 nm to 1000 nm.

23) In 1-22), the III-V compound includes binary III-V compounds, such as GaAs, GaP, InP, InAs, AlP, AlAs, AlSb, GaSb, AlN GaN and InN, and ternary and quaternary III-V compounds by mixing the binary III-V compounds.

24) In 1-22), the III-V compound is replaced with a II-VI compound, wherein the II-VI compound include binary II-VI compounds, such as ZnSe, ZnS, CdTe, HgTe, ZnO, and MgS, and ternary and quaternary II-VI compounds by mixing the binary II-VI compounds.

25) A decomposition stop layer of silicon (Si) with a higher sublimation temperature or melting point is grown on or above a decomposition layer of a material with a lower sublimation temperature or lower melting point and then the temperature is increased to decompose or melt the decomposition layer material with the lower sublimation temperature or melting point.

26) In 25) wherein the decomposition layer material is germanium (Ge).

27) A decomposition stop layer of silicon (Si) is grown on or above a decomposition layer of a different material from Si, and then the decomposition layer is decomposed by annealing, laser abrasion, ion implantation and other methods.

28) An Si substrate, wherein ions are implanted with a certain depth from a top surface to form a decomposition layer which has a lower sublimation temperature or melting point. Then, the Si substrate is annealed at a high temperature to decompose or melt the decomposition layer with the lower sublimation temperature or melting point. An upper layer from the decomposed decomposition layer is a decomposition stop layer of Si.

29) In 28), the ions include at least Ge, In, Ga, Al, oxygen (O) and others.

30) In 25-29), a III-V compound or silicon carbide (SiC) based device structure is grown on or above a decomposition stop layer of Si.

31) In 30), the III-V compound or silicon carbide (SiC) based device structure includes at least an n-type layer.

32) In 30), the III-V compound or silicon carbide (SiC) based device structure includes at least a p-type layer.

33) In 30), the III-V compound or silicon carbide (SiC) based device structure includes at least an n-type layer and a p-type layer.

34) In 30), the III-V compound or silicon carbide (SiC) based device structure includes at least n-type layers, an active (emitting) layer and p-type layers.

35) In 30-34), the III-V compound or silicon carbide (SiC) based device includes all kinds of devices, such as LEDs, LDs, photodetectors, power devices, radio frequency (RF) devices, high electron mobility transistors (HEMTs), field effect transistors (FETs), and other opto-electronic devices.

36) In 35), the III-V compound or silicon carbide (SiC) based device is used for automobiles including electric vehicles (EVs), data centers, power grids, computers, robots, smartphones, TVs, base stations of wireless communications, all kinds of communication systems, displays, lighting, trains, airplanes, and all kinds of equipment and systems.

37) III-V compound or silicon carbide (SiC) based layers with a grown area of more than 100 μm², wherein an in-plane lattice constant or strain of at least one III-V compound or silicon carbide (SiC) based layer is biaxially relaxed more than 20%.

38) III-V compound or silicon carbide (SiC) based devices with a chip size of more than 100 μm², wherein an in-plane lattice constant or strain of at least one III-V compound or silicon carbide (SiC) based layer is biaxially relaxed more than 20%.

39) III-V compound or silicon carbide (SiC) based layers, wherein an in-plane lattice constant or strain of at least one III-V compound or silicon carbide (SiC) based layer is biaxially relaxed more than 20%.

40) III-V compound or silicon carbide (SiC) based devices, wherein an in-plane lattice constant or strain of at least one III-nitride or silicon carbide (SiC) based layer is biaxially relaxed more than 20%.

41) III-V compound or silicon carbide (SiC) based layers, wherein an in-plane lattice constant or strain of at least one III-V compound based or silicon carbide (SiC) layer is biaxially relaxed more than 50%.

42) III-V compound or silicon carbide (SiC) based devices, wherein an in-plane lattice constant or strain of at least one III-V compound or silicon carbide (SiC) based layer is biaxially relaxed more than 50%.

43) In 27-42), the III-V compound or silicon carbide (SiC) based layers or devices include all kinds of devices, such as LEDs, LDs, photodetectors, power devices, radio frequency (RF) devices, high electron mobility transistors (HEMTs), field effect transistors (FETs), and other opto-electronic devices.

44) In 43), the III-V compound or silicon carbide (SiC) based layers or devices are used for automobiles including electric vehicles (EVs), data centers, power grids, computers, robots, smartphones, TVs, base stations of wireless communications, all kinds of communication systems, displays, lighting, trains, airplanes, and all kinds of equipment and systems.

45) In 25-44), the thickness of the decomposition layer is less than 50 nm.

46) In 25-44), the thickness of the decomposition layer is less than 10 nm.

47) In 25-44), the thickness of the decomposition stop layer is from 10 nm to 1000 nm.

48) In 25-44), the III-V compound or silicon carbide (SiC) based layer is grown with a thickness more than 1 μm on or above decomposition stop layer of Si.

49) In 25-44), the III-V compound or silicon carbide (SiC) based layer is grown with a thickness more than 5 μm on or above decomposition stop layer of Si.

50) In 25-44), the III-V compound or silicon carbide (SiC) based layer is grown with a thickness more than 10 μm on or above decomposition stop layer of Si.

51) In 48-50), wherein the III-V compound or silicon carbide (SiC) based layer is used as a substrate in order to grow a device structure.

52) In 48-50), wherein the III-V compound or silicon carbide (SiC) based layer is used as a substrate after removing the Si material.

53) In 25-52), the III-V compound is comprised of binary III-V compounds, such as GaAs, GaP, InP, InAs, AlP, AlAs, AlSb, GaN, InN, AlN and GaSb, and ternary and quaternary III-V compounds by mixing the binary III-V compounds.

### Process Flowchart

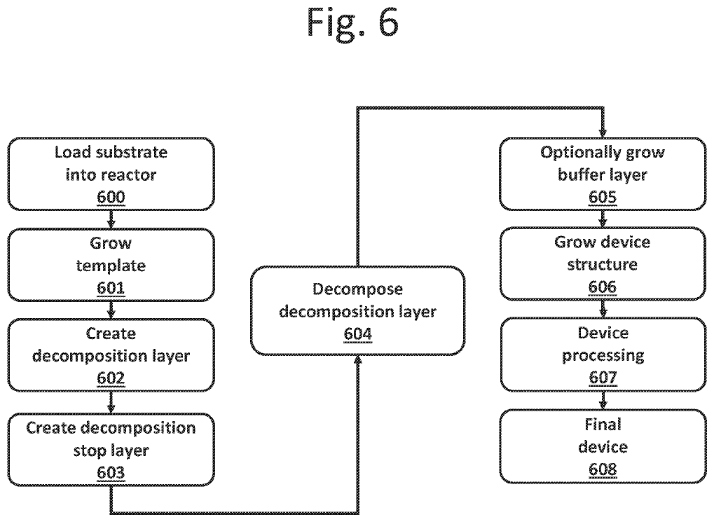

FIG. 6 is a flowchart that illustrates the steps for a process of III-V, II-VI in-situ compliant substrate formation and resulting devices, according to the present invention. Specifically, the flowchart illustrates the steps for a process of fabricating a III-V or II-VI based device having an in-plane lattice constant or strain that is at least 20% biaxially relaxed, preferably more than 20% biaxially relaxed, more preferably 50% or more biaxially relaxed, and most preferably at least 70% biaxially relaxed.

Block 600 represents the step of loading a substrate into a chamber of an MOCVD reactor. The substrate may comprise GaAs, Si, InP, or other materials.

Block 601 represents the optional step of growing a III-V or II-VI compound based template on or above the substrate.

Block 602 represents the step of creating a III-V or II-VI compound based decomposition layer on or above the III-V or II-VI compound based template and/or substrate. In one embodiment, the III-V or II-VI compound based decomposition layer consists of a single layer, rather than multiple layers.

Block 603 represents the step of creating a III-V or II-VI compound based decomposition stop layer on or above the III-nitride based decomposition layer.

Block 604 represents the step of decomposing the III-V or II-VI compound based decomposition layer, but not the III-V or II-VI compound based decomposition stop layer, by a temperature increase. In this step, the III-V or II-VI compound based decomposition layer may be decomposed by increasing a growth temperature of the III-V or II-VI compound based decomposition stop layer, or by thermal annealing, or by laser abrasion, or by ion implantation, or by other methods.

Block 605 represents the optional step of epitaxially growing a III-V or II-VI compound based buffer layer on or above the III-V or II-VI compound based decomposition stop layer after the III-V or II-VI compound based decomposition layer is decomposed.

Block 606 represents the step of epitaxially growing a III-V or II-VI compound based device structure on or above the III-V or II-VI compound based decomposition stop layer. The III-V or II-VI compound based device structure includes at least one of an n-type layer, active (or emitting) layer, and p-type layer. The at least one of the n-type layer, active (or emitting) layer and p-type layer has an in-plane lattice constant or strain that is at least 20% biaxially relaxed, preferably more than 20% biaxially relaxed, more preferably 50% or more biaxially relaxed, and most preferably at least 70% biaxially relaxed.

The III-V compound may be a binary, ternary or quaternary alloy containing elements from group III (B, Al, Ga, In) and group V (N, P, As, Sb), including binary III-V compounds such as GaAs, GaP, InP, InAs, AlP, AlAs, AlSb, GaSb, AlN GaN, and InN, and ternary and quaternary III-V compounds resulting from mixing the binary III-V compounds.

The II-VI compound may include binary II-VI compounds such as ZnSe, ZnS, CdTe, HgTe, ZnO, and MgS, and ternary and quaternary II-VI compounds resulting from mixing the binary II-VI compounds.

The III-V or II-VI compound based device structure may be comprised of III-V or II-VI compound based layers with an area or size of more than 100 μm², and an in-plane lattice constant or strain of at least one of the of III-V or II-VI compound based layers is biaxially relaxed more than 50%; and more preferably, the in-plane lattice constant or strain of at least one of the of III-V or II-VI compound based layers is at least 70% biaxially relaxed.

The III-V or II-VI compound based decomposition layer may have a thickness of less than 50 nm; and more preferably, the III-V or II-VI compound based decomposition layer may have a thickness of less than 10 nm. The III-V or II-VI compound based decomposition stop layer may have a thickness of 10 nm to 1000 nm.

In one embodiment, the III-V or II-VI compound based decomposition stop layer comprises Si, the III-V or II-VI compound based decomposition layer comprises Ge, and the III-V or II-VI compound based device structure comprises one or more SiC layers. At least one of the SiC layers may have an area or size that is more than 100 μm², and the at least one of the SiC layers may be biaxially relaxed more than 20%, and more preferably, the at least one of the SiC layers may be biaxially relaxed more than 50%. At least one of the SiC layers may have a thickness of more than 1 μm; more preferably, the at least one of the SiC layers may have a thickness of more than 5 μm, and most preferably, the at least one of the SiC layers may have a thickness of more than 10 μm. The SiC layers may be used as a substrate to grow the III-V or II-VI compound based device structure, after the III-V or II-VI compound based decomposition stop layer that comprises Si is removed.

Once complete, the III-V or II-VI compound based device structure may be flip-chip bonded on a sub-mount, and the III-V or II-VI compound based device structure may be separated from the decomposed III-V or II-VI compound based decomposition layer. This separation may be performed by etching or mechanical pressure.

Block 607 represents the step of processing the III-V or II-VI compound based device structure into a III-V or II-VI compound based device, and then packaging the device. This may include, but is not limited to, depositing other layers, sub-mounting, etching mesas or ridge waveguides, passivating sidewalls, depositing electrodes, etc.

Block 608 represents the end result of the process, namely, a III-V or II-VI compound based device having an in-plane lattice constant or strain that is more than 20% biaxially relaxed, including a III-V or II-VI compound based decomposition stop layer created on or above a III-V or II-VI compound based decomposition layer, wherein the III-V or II-VI compound based decomposition stop layer has a higher sublimation temperature or melting point as compared to a lower sublimation temperature or melting point of the III-V or II-VI compound based decomposition layer, wherein the III-V or II-VI compound based decomposition layer is decomposed, but not the III-V or II-VI compound based decomposition stop layer; and a III-V or II-VI compound based device structure grown on or above the III-V or II-VI compound based decomposition stop layer.

The III-V or II-VI compound based device may comprise a light-emitting diode (LED), laser diode (LD), photodetector, power device, radio frequency (RF) device, high electron mobility transistor (HEMT), field effect transistor (FE), or other opto-electronic device.

In an alternative embodiment, Blocks 602 and 603 may represent the steps of creating the III-V or II-VI compound based decomposition layer by ion implantation into the III-V or II-VI compound based template or substrate, wherein Aluminum (Al), Indium (In), Gallium (Ga), Germanium (Ge) or Oxygen (B) ions are implanted to a specified depth from a top surface of the III-V or II-VI compound based template or substrate to form the III-V or II-VI compound based decomposition layer with a lower sublimation temperature or melting point, and the III-V or II-VI compound based decomposition layer is annealed at or above the lower sublimation temperature or melting point to decompose or melt the III-V or II-VI compound based decomposition layer.

The above steps may be modified, eliminated, repeated, or completed in any desired order, without departing from the scope of the present invention.

### REFERENCES

The following publications are incorporated by reference herein:
[1] “High Brightness Light Emitting Diodes” G. B. Stringfellow and M. G. Craford, Semiconductors and Semimetals, Vol. 48, 1997.
[2] “Targeting telecoms with nanowires”, WWW.compoundsemiconductor.NET, issue, 2021, page 46-50.

What is claimed is:

1. A method, comprising:
fabricating a III-V or II-VI compound based device having an in-plane lattice constant or strain that is at least 20% biaxially relaxed by:
creating a III-V or II-VI compound based decomposition stop layer on or above a III-V or II-VI compound based decomposition layer, wherein the III-V or II-VI compound based decomposition stop layer has a higher sublimation temperature or melting point as compared to a lower sublimation temperature or melting point of the III-V or II-VI compound based decomposition layer, and a temperature increase decomposes the III-V or II-VI compound based decomposition layer; and
growing a III-V or II-VI compound based device structure on or above the III-V or II-VI compound based decomposition stop layer.

2. The method of claim 1, wherein the III-V or II-VI compound based decomposition layer is created by ion implantation with a certain depth from a top surface of a III-V or II-VI compound based substrate or a III-V or II-VI compound based template grown on a substrate, and the III-V or II-VI compound based decomposition layer is annealed at or above the lower sublimation temperature or melting point to decompose or melt the III-V or II-VI compound based decomposition layer.

3. The method of claim 2, wherein the ion implantation implants ions selected from a group including at least Ge, In, Ga, Al, and O.

4. The method of claim 1, wherein the III-V or II-VI compound based device structure includes one or more of an n-type layer, an active or emitting layer, and/or a p-type layer.

5. The method of claim 1, wherein the III-V or II-VI compound based device structure is flip-chip bonded on a sub-mount, and the III-V or II-VI compound based device structure is separated from the decomposed III-V or II-VI compound based decomposition layer.

6. The method of claim 1, wherein the III-V or II-VI compound based device comprises a light-emitting diode (LED), laser diode (LD), photodetector, power device, radio frequency (RF) device, high electron mobility transistor (HEMT), field effect transistor (FET), or other opto-electronic device.

7. The method of claim 1, wherein the III-V or II-VI compound based device structure is comprised of III-V or II-VI compound based layers with an area or size of more than 100 μm², and an in-plane lattice constant or strain of at least one of the of III-V or II-VI compound based layers is 50% or more biaxially relaxed.

8. The method of claim 7, wherein the in-plane lattice constant or strain of at least one of the of III-V or II-VI compound based layers is at least 70% biaxially relaxed.

9. The method of claim 1, wherein the III-V or II-VI compound based decomposition layer has a thickness of less than 50 nm.

10. The method of claim 9, wherein the III-V or II-VI compound based decomposition layer has a thickness of less than 10 nm.

11. The method of claim 1, wherein the III-V or II-VI compound based decomposition stop layer has a thickness of 10 nm to 1000 nm.

12. The method of claim 1, wherein the III-V compound is a binary, ternary or quaternary alloy containing elements from group III (B, Al, Ga, In) and group V (N, P, As, Sb), including binary III-V compounds such as GaAs, GaP, InP, InAs, AlP, AlAs, AlSb, GaSb, AlN GaN, and InN, and ternary and quaternary III-V compounds resulting from mixing the binary III-V compounds.

13. The method of claim 1, wherein the II-VI compound includes binary II-VI compounds such as ZnSe, ZnS, CdTe, HgTe, ZnO, and MgS, and ternary and quaternary II-VI compounds resulting from mixing the binary II-VI compounds.

14. The method of claim 1, wherein the III-V or II-VI compound based decomposition layer is decomposed by increasing a growth temperature of the III-V or II-VI compound based decomposition top layer, annealing, laser abrasion, ion implantation, or other methods.

15. The method of claim 1, wherein the III-V or II-VI compound based decomposition stop layer comprises Si, the III-V or II-VI compound based decomposition layer comprises Ge, and the III-V or II-VI compound based device structure comprises one or more SiC layers.

16. The method of claim 15, wherein at least one of the SiC layers has an area or size that is more than 100 μm², and the at least one of the SiC layers is at least 20% biaxially relaxed.

17. The method of claim 16, wherein the at least one of the SiC layers is more than 50% biaxially relaxed.

18. The method of claim 15, wherein at least one of the SiC layers has a thickness of more than 1 μm.

19. The method of claim 18, wherein the at least one of the SiC layers has a thickness of more than 5 μm.

20. The method of claim 19, wherein the at least one of the SiC layers has a thickness of more than 10 μm.

21. The method of claim 15, wherein the SiC layers are used as a substrate to grow the III-V or II-VI compound based device structure after the III-V or II-VI compound based decomposition stop layer that comprises Si is removed.

22. A device, comprising:
a III-V or II-VI compound based device having an in-plane lattice constant or strain that is at least 20% biaxially relaxed including:
a III-V or II-VI compound based decomposition stop layer created on or above a III-V or II-VI compound based decomposition layer, wherein the III-V or II-VI compound based decomposition stop layer has a higher sublimation temperature or melting point as compared to a lower sublimation temperature or melting point of the III-V or II-VI compound based decomposition layer, wherein the III-V or II-VI compound based decomposition layer is decomposed, but not the III-V or II-VI compound based decomposition stop layer; and
a III-V or II-VI compound based device structure grown on or above the ITT-V or IT-VI compound based decomposition stop layer.

23. A product-by-process, comprising:
a III-V or II-VI compound based device having an in-plane lattice constant or strain that is at least 20% biaxially relaxed including:
a III-V or II-VI compound based decomposition stop layer created on or above a III-V or II-VI compound based decomposition layer, wherein the III-V or II-VI compound based decomposition stop layer has a higher sublimation temperature or melting point as compared to a lower sublimation temperature or melting point of the III-V or II-VI compound based decomposition layer, wherein the III-V or II-VI compound based decomposition layer is decomposed, but not the III-V or II-VI compound based decomposition stop layer; and
a III-V or II-VI compound based device structure grown on or above the III-V or II-VI compound based decomposition stop layer;
wherein the III-V or II-VI compound based device having the in-plane lattice constant or strain that is at least 20% biaxially relaxed is fabricated by:
creating the III-V or II-VI compound based decomposition stop layer on or above the III-V or II-VI compound based decomposition layer, wherein the III-V or II-VI compound based decomposition stop layer has a higher sublimation temperature or melting point as compared to a lower sublimation temperature or melting point of the III-V or II-VI compound based decomposition layer, and a temperature increase decomposes the III-V or II-VI compound based decomposition layer; and
growing the III-V or II-VI compound based device structure on or above the ITT-V or IT-VI compound based decomposition stop layer.
